(19) United States
(12) Patent Application Publication
(10) Pub. No.: US 2016/0131977 A1
(43) Pub. Date: May 12, 2016

(54) METHOD FOR FABRICATING PERIPHERAL WIRING UNIT OF TOUCH PANEL

(71) Applicant: Innolux Corporation, Miao-Li County (TW)

(72) Inventors: Chao-Wen LEE, Miao-Li County (TW); Hung-Sheng CHO, Miao-Li County (TW); Tung-Chang TSAI, Miao-Li County (TW)

(21) Appl. No.: 14/995,232

(22) Filed: Jan. 14, 2016

Related U.S. Application Data
(62) Division of application No. 13/873,296, filed on Apr. 30, 2013.

(30) Foreign Application Priority Data
May 4, 2012 (TW) 101116007

(51) Int. Cl. G03F 7/20; G03F 7/36; G06F 3/047; G03F 7/32

(52) U.S. Cl. CPC G03F 7/20; G03F 7/32; G03F 7/2022; G03F 7/36; G06F 3/047; G06F 2203/04103

(57) ABSTRACT

A method for fabricating a peripheral wiring unit of a touch panel includes the following steps: (a) forming a transparent conductive layer on a substrate, the substrate including a peripheral region and a window region surrounded by the peripheral region, and forming a photosensitive conductive layer on the peripheral region of the substrate, such that the photosensitive conductive layer at least partially overlies the transparent conductive layer; (b) exposing the photosensitive conductive layer by using a photomask; and (c) developing the exposed photosensitive conductive layer to form a peripheral wiring unit on the peripheral region of the substrate.

### CROSS-REFERENCE TO RELATED APPLICATION

This is a divisional application of U.S. patent application Ser. No. 13/873,296, filed on Apr. 30, 2013, which claims the priority of Taiwanese Patent Application No. 101116007, filed on May 4, 2012. This application claims the benefits and priority of all these prior applications and incorporates by reference the contents of these prior applications in their entirety.

### BACKGROUND

1. Field

This invention relates to a method for fabricating a peripheral wiring unit of a touch panel, more particularly to a method for fabricating a peripheral wiring unit on a peripheral region of the touch panel, and a touch panel and a touch screen display apparatus containing the peripheral wiring unit.

2. Description of the Related Art

With the popularization of portable electronic devices, touch screen interface and related techniques are being developed rapidly. Moreover, with miniaturization of the portable electronic devices, miniaturizing a touch panel is highly required. Among touch panels, a projected capacitive touch panel (PCTP) has become a mainstream in the industry due to the characteristics of lightness, slimness, anti-interference, and multi-touch. It is necessary for the capacitive touch panel to be formed with a peripheral wiring unit in a relatively small peripheral region. A conventional method for forming the peripheral wiring unit is conducted by screen printing a silver paste material on a predetermined wire-depositing position of the peripheral region of the touch panel. However, in the conventional method for forming the peripheral wiring unit, printing uniformity is likely to be influenced by the physical property of the silver paste so that wire integrity of the peripheral wiring unit might be poor, thereby adversely affecting signal output. Moreover, tension of a screen and times of printing also influence precision of the peripheral wiring unit made of the silver paste. Therefore, the conventional method for forming the peripheral wiring unit using screen printing is likely to be limited by characteristics of a printing material, tension of the screen, and times of printing so that precision of the peripheral wiring unit is unable to be effectively improved. In order to maintain the reliability of the peripheral wiring unit of the touch panel and prevent short circuit that is attributed to contact of two adjacent wires and that would result in signal interference or signal error, in the current trend of reduced line width of the wires, it is necessary to develop a new wire fabricating technique capable of overcoming low precision and poor wire integrity problems encountered in the conventional method.

### SUMMARY

Therefore, an object of the present invention is to provide a method for fabricating a peripheral wiring unit of a touch panel, more particularly to a method for fabricating a peripheral wiring unit with higher position precision and higher wire integrity.

According to one aspect of this invention, a method for fabricating a peripheral wiring unit of a touch panel comprises the following steps:

(a) forming a transparent conductive layer on a substrate, the substrate including a peripheral region and a window region surrounded by the peripheral region, and forming a photosensitive conductive layer on the peripheral region of the substrate, such that the photosensitive conductive layer at least partially overlies the transparent conductive layer;

(b) exposing the photosensitive conductive layer by using a photomask; and

(c) developing the exposed photosensitive conductive layer to form a peripheral wiring unit on the peripheral region of the substrate.

The effect of the method of this invention resides in that a photosensitive conductive material is applied in forming the peripheral wiring unit in the narrow peripheral region of the touch panel in combination with exposure and development techniques. Therefore, line width and line spacing between two adjacent ones of wires of the peripheral wiring unit are reduced while superior position precision and wire integrity of the peripheral wiring unit are still maintained. Accordingly, short-circuit of adjacent wires can be avoided, and the area for the peripheral wiring unit can be reduced, thereby relatively widening a window region of the touch panel.

According to another aspect of this invention, a touch panel including a peripheral wiring unit made using the aforesaid method is provided.

The touch panel of this invention comprises a substrate and a peripheral wiring unit disposed on the substrate.

The substrate has a window region and a peripheral region surrounding the window region, and includes a patterned transparent electrode unit.

The patterned transparent electrode unit is made of a transparent conductive material and is formed on the window region.

The peripheral wiring unit is formed on the peripheral region of the substrate by photolithographing a photosensitive conductive material, and is electrically connected to the transparent electrode unit.

According to yet another aspect of this invention, a touch screen display apparatus containing a peripheral wiring unit made using the aforesaid method is further provided in this invention.

The touch screen display apparatus of this invention comprises the aforesaid touch panel and a display panel. The display panel is disposed on the transparent electrode unit of the touch panel.

### BRIEF DESCRIPTION OF THE DRAWINGS

Other features and advantages of the present invention will become apparent in the following detailed description of the preferred embodiments of the invention, with reference to the accompanying drawings, in which:

FIG. 1 is a perspective view showing the first preferred embodiment of a method for fabricating a peripheral wiring unit of a touch panel according to this invention, which illustrates the step of forming a photosensitive conductive layer on a substrate;

FIG. 2 is a schematic side view of FIG. 1, showing a combination structure of the substrate and the photosensitive conductive layer;

FIG. 3 is a schematic side view showing the step of forming a photoresist layer on the combination structure of FIG. 2;

FIG. 4 is an exploded perspective view showing an exposure step using a photomask in the first preferred embodiment;

FIG. 5 is a cross-sectional diagram taken along line V-V in FIG. 4, which shows the exposure step using the photomask;

FIG. 6 is a cross-sectional diagram showing formation of a patterned photoresist layer after the photoresist layer is developed using a developer;

FIG. 7 is a cross-sectional diagram showing formation of a peripheral wiring unit after the photosensitive conductive layer is developed;

FIG. 8 is a cross-sectional diagram showing etching of a transparent conductive layer exposed from the patterned photoresist layer in the first preferred embodiment;

FIG. 9 is a cross-sectional diagram showing the step of removing the patterned photoresist layer in the first preferred embodiment;

FIG. 10 is a schematic view showing a touch panel fabricated according to the first preferred embodiment;

FIG. 11 is a perspective view showing the second preferred embodiment of a method for fabricating a peripheral wiring unit of a touch panel according to this invention, which illustrates a substrate formed with a transparent electrode unit;

FIG. 12 is a perspective view showing formation of a photosensitive conductive layer on the substrate in the second preferred embodiment;

FIG. 13 is an exploded perspective view showing an exposure step using a photomask in the second preferred embodiment;

FIG. 14 is a cross-sectional diagram taken along line XIV-XIV in FIG. 13, which shows the exposure step using the photomask;

FIG. 15 is a cross-sectional diagram showing formation of a peripheral wiring unit after a development step is conducted in the second preferred embodiment;

FIG. 16 is a schematic view showing the preferred embodiment of a touch screen display apparatus of this invention;

FIG. 17 is an enlarged view showing a peripheral wiring unit fabricated by a conventional screen printing process; and

FIG. 18 is an enlarged view showing a peripheral wiring unit fabricated according to the method of this invention.

### DETAILED DESCRIPTION

Before the present invention is described in greater detail, it should be noted herein that like elements are denoted by the same reference numerals throughout the disclosure.

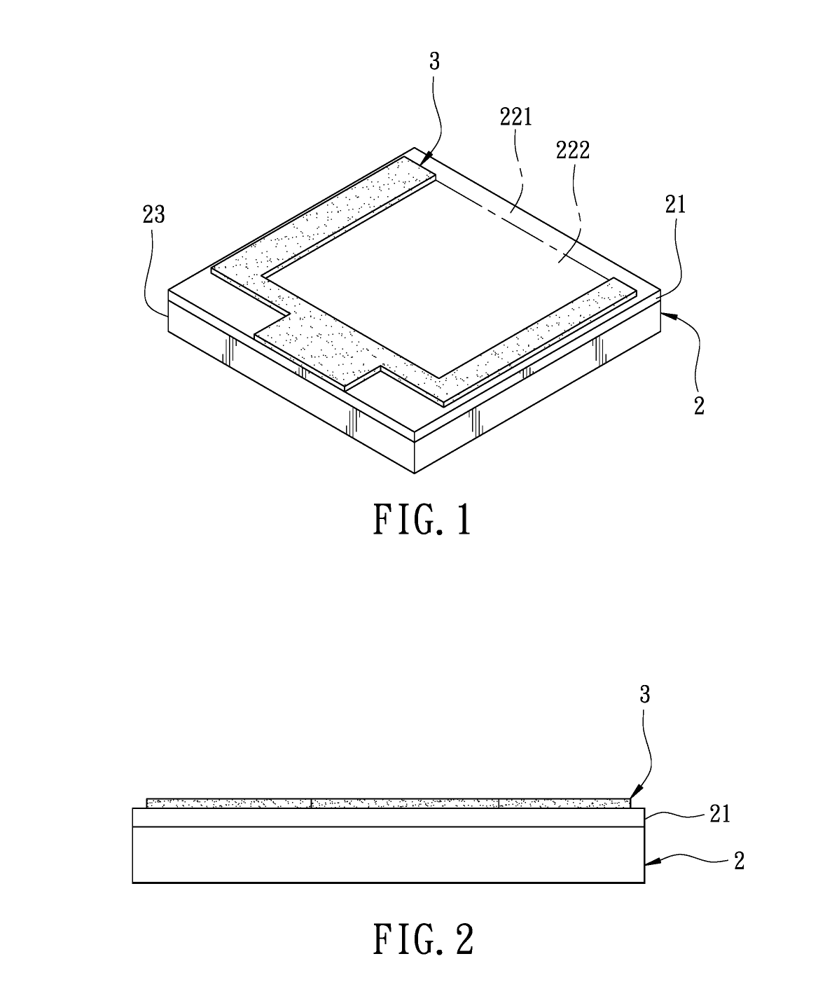

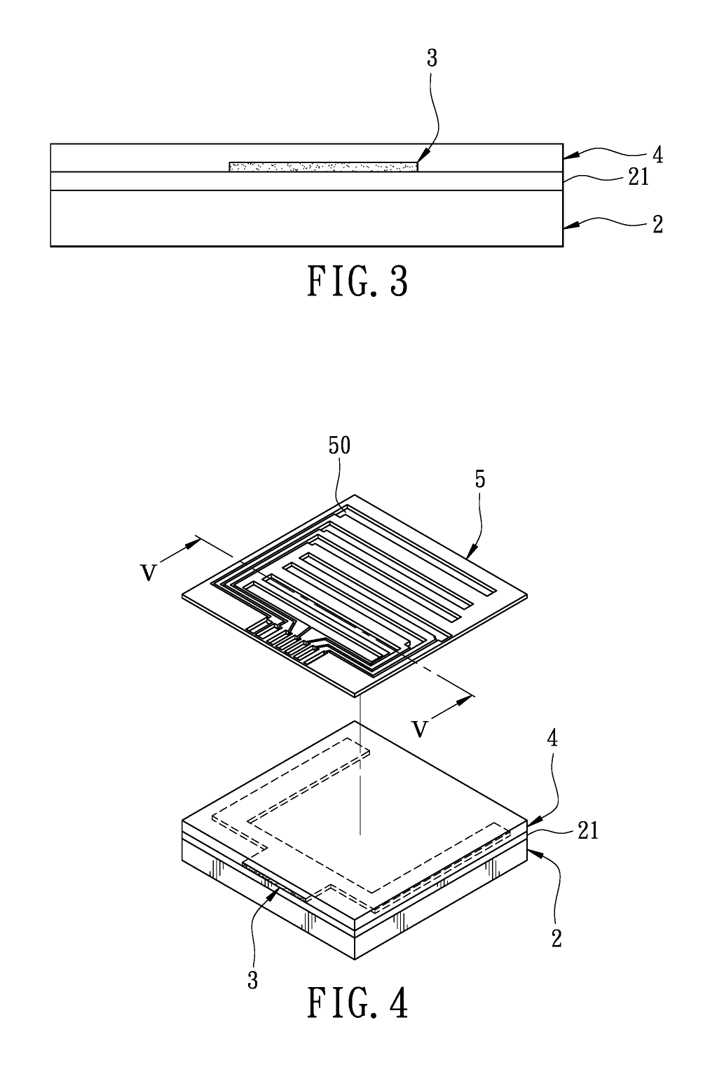

Referring to FIGS. 1 to 10, consecutive steps of a method for fabricating a peripheral wiring unit of the first preferred embodiment according to this invention are shown. FIG. 2 is a side view of FIG. 1. The steps are illustrated below.

Referring to FIGS. 1 to 3, a photosensitive conductive layer 3 is formed on a peripheral region 221 of a substrate 2 that includes a transparent conductive layer 21. The photosensitive conductive layer 3 overlies the transparent conductive layer 21. Preferably, the photosensitive conductive layer 3 has a thickness ranging from 3 μm to 10 μm. In this embodiment, the substrate 2 further includes a transparent plate 23 on which the transparent conductive layer 21 is formed. The photosensitive conductive layer 3 is formed on the transparent conductive layer 21 opposite to the transparent plate 23.

In this embodiment, the photosensitive conductive layer 3 is made from a photosensitive conductive material composed of a thermosetting photosensitive material and a plurality of electrically conductive particles. The ratio of the thermosetting photosensitive material to the electrically conductive particles ranges from 80:20 to 90:10. Preferably, the photosensitive conductive material has a viscosity ranging from 15000 mPa·S to 25000 mPa·S, and a volume resistivity ranging from 1.5*10⁻⁶ Ω·cm to 2.5*10⁻⁶ Ω·cm. The electrically conductive particles are gold particles, silver particles, copper particles, aluminum particles, nickel particles, or combinations thereof. In this embodiment, silver particles are used as the electrically conductive particles.

The substrate 2 further includes a window region 222 surrounded by the peripheral region 221. The transparent conductive layer 21 is made of a transparent conductive material, and is formed on the peripheral region 221 and the window region 222. The photosensitive conductive layer 3 is completely overlaid on the transparent conductive layer 21 on the peripheral region 221 of the substrate 2. The transparent conductive material can be indium tin oxide (ITO) or indium zinc oxide (IZO). It should be noted that the transparent conductive layer 21 can be partially overlaid with the photosensitive conductive layer 3.

Moreover, after the photosensitive conductive layer 3 is formed, a photoresist layer 4 is formed to cover the transparent conductive layer 21 of the substrate 2 and the photosensitive conductive layer 3. In this embodiment, the photoresist layer 4 is made of a negative photoresist.

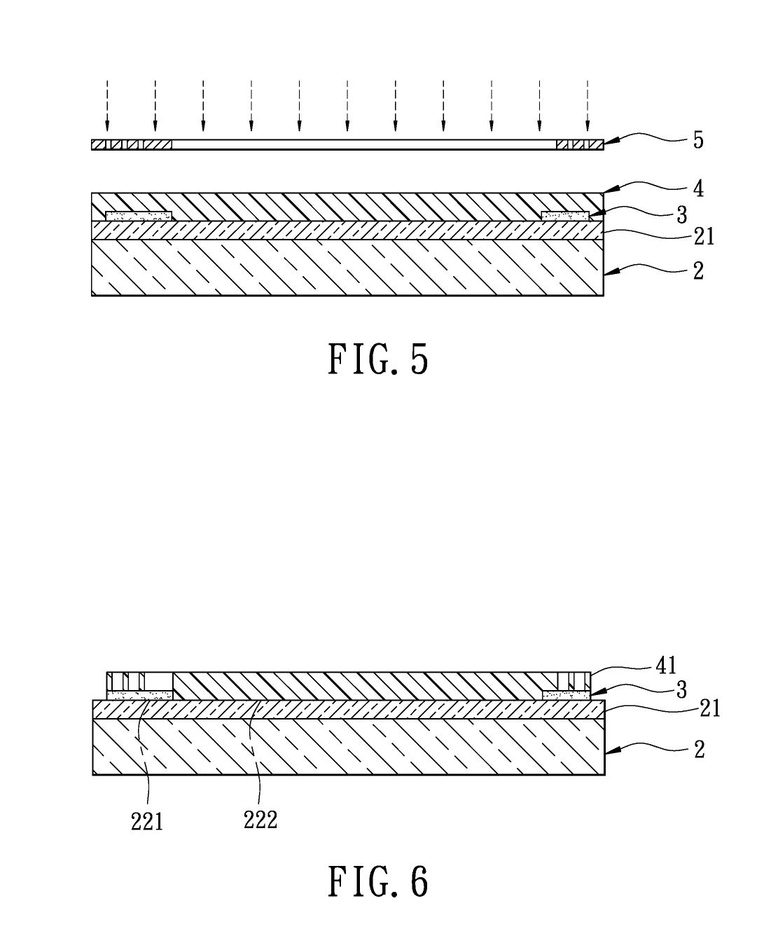

Referring to FIGS. 4 and 5, the photoresist layer 4 and the photosensitive conductive layer 3 under the photoresist layer 4 are exposed using a photomask 5. A light source used for exposure in this embodiment is ultraviolet light from a lamp, such as a high pressure mercury lamp with luminance ranging from 17 mW/cm² to 35 mW/cm² and exposure dose ranging from 20 mJ/cm² to 200 mJ/cm².

The photomask 5 has a plurality of light transmissible regions 50 corresponding in position to a wiring unit-forming portion of the peripheral region 221 and an electrode unit-forming region of the window region 222 of the substrate 2. The photoresist layer 4 and the photosensitive conductive layer 3 corresponding in position to the wiring unit-forming portion and the window region 222 are exposed from ultraviolet light that penetrates through the light transmissible regions 50 of the photomask 5 and are thus cured.

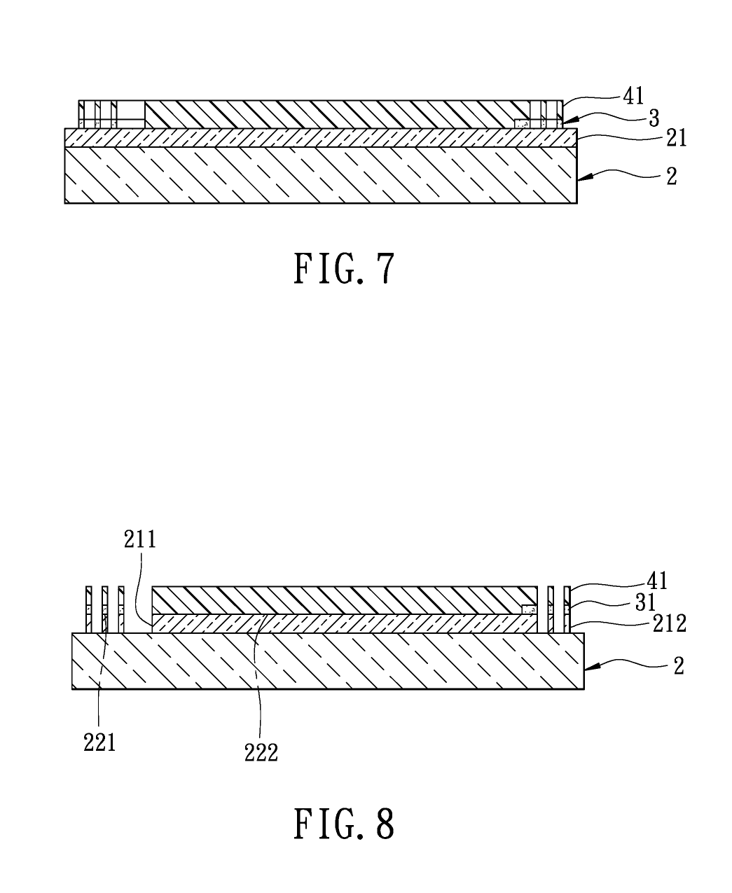

Referring to FIGS. 6 and 7, the photoresist layer 4 and the photosensitive conductive layer 3 thus exposed are subjected to development. Specifically, the photoresist layer 4 is firstly subjected to development. The unexposed portion of the photoresist layer 4 is removed using a developer which is selected from the group consisting of potassium hydroxide, sodium hydroxide, sodium carbonate, and sodium bicarbonate. Accordingly, the photoresist layer 4 is formed into a patterned photoresist layer 41.

Then, the photosensitive conductive layer 3 under the patterned photoresist layer 41 is developed. Specifically, the unexposed portion of the photosensitive conductive layer 3 is removed by virtue of a developer selected from the group consisting of potassium hydroxide, sodium hydroxide, and sodium bicarbonate. Accordingly, on the peripheral region 21 of the substrate 2, a patterned peripheral wiring unit 31 is formed. The peripheral wiring unit 31 has a pattern identical to that of the patterned photoresist layer 41 on the peripheral region 21, and the peripheral wiring unit 31 underlies the patterned photoresist layer 41 on the peripheral region 21.

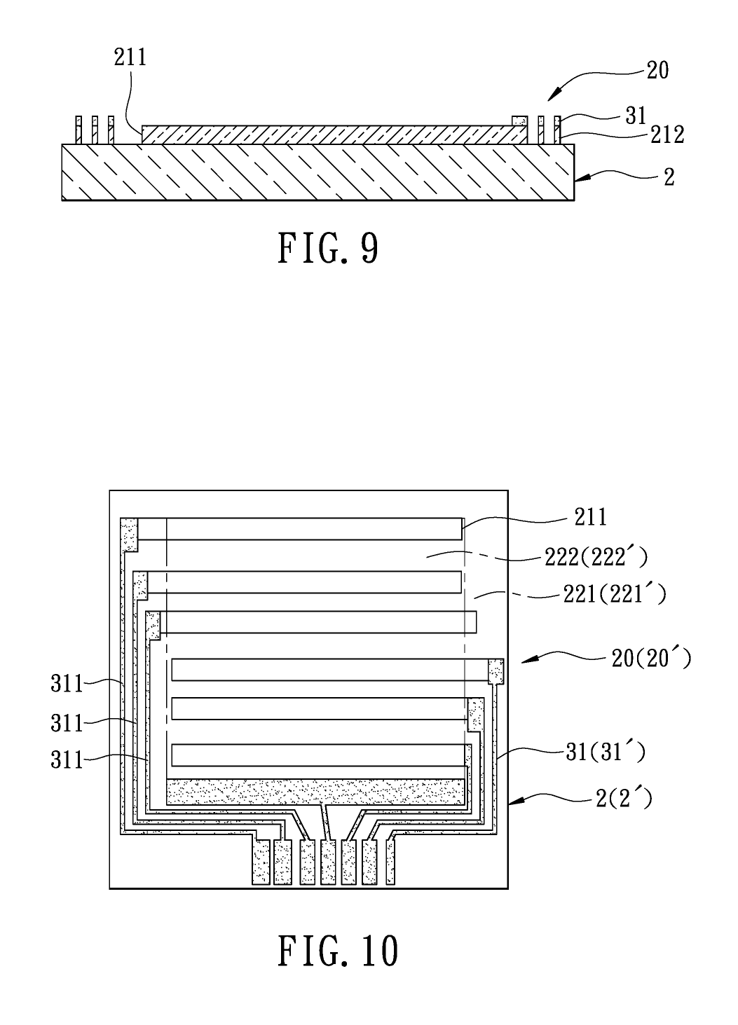

Referring to FIGS. 8 and 9, the transparent conductive layer 21 that is uncovered by the patterned photoresist layer 41 is etched until the substrate 2 is exposed. The patterned photoresist layer 41 is then removed after etching is completed so that a patterned transparent electrode unit 211 is formed on the window region 222 and a patterned peripheral transparent lead unit 212 is formed on the peripheral region 221 underneath the peripheral wiring unit 31. Patterns of the transparent electrode unit 211 and the peripheral transparent lead unit 212 are identical to those of the light transmissible regions 50 of the photomask 5. The peripheral wiring unit 31 overlays on the peripheral transparent lead unit 212.

After the patterned photoresist layer 41 is removed, a touch panel 20 shown in FIGS. 9 and 10 is thus formed. Since the photosensitive conductive material is a thermosetting material, in order to further stabilize the structure of the peripheral wiring unit 31, the peripheral wiring unit 31 is preferably further subjected to a hot baking process so as to improve degree of curing for the peripheral wiring unit 31. The touch panel 20 can be packaged with other electronic components to form a display apparatus.

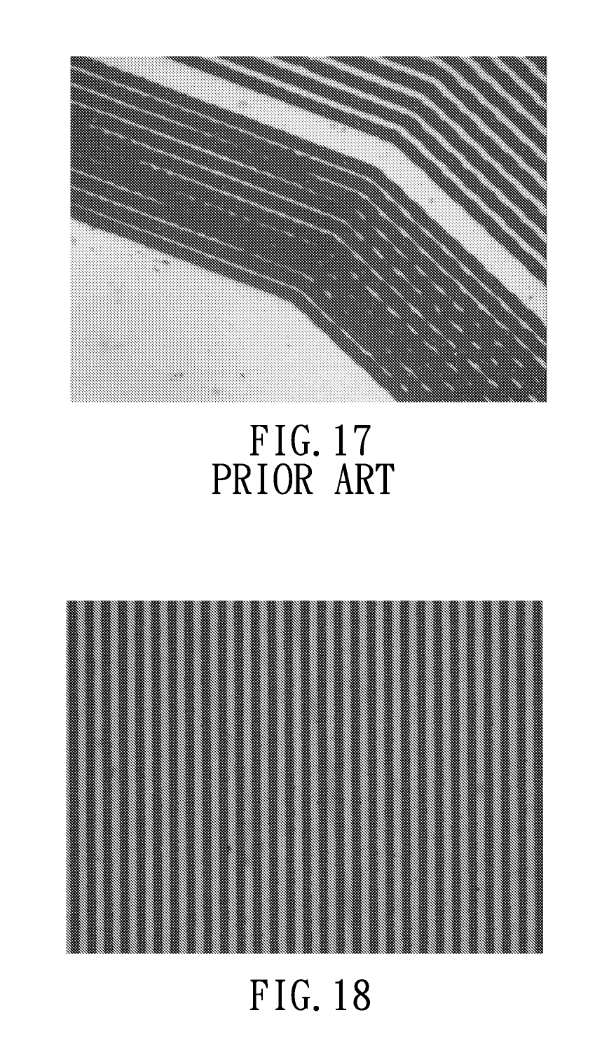

FIG. 17 shows a plurality of peripheral wires fabricated by the conventional screen printing process. The peripheral wires have a minimum width of 100 μm, and a minimum wiring spacing of 100 μm between two adjacent ones of the peripheral wires. Due to the outflow of a printing material, the peripheral wires present problems of inconsistent width and short-circuit attributed to contact of two adjacent ones of the peripheral wires. FIG. 18 illustrates the peripheral wiring unit 31 fabricated according to the method of this invention. The picture shows that each of peripheral wires of the peripheral wiring unit 31 has a straight peripheral edge and has uniform line width, and every line spacing between two adjacent ones of the peripheral wires is uniform. Accordingly, the method of this invention improves the precision of the peripheral wiring unit 31 of the touch panel 20. Moreover, since the peripheral wiring unit 31 is fabricated from a piece of the flat photosensitive conductive layer 3, the thickness and the integrity of the piece of the flat photosensitive conductive layer 3 are relatively easy to be controlled, thereby resulting in consistent thickness and superior wire integrity for all of the peripheral wires. According to the method of this invention, the line width of each of the peripheral wires and the line spacing between two adjacent ones of the peripheral wires can be reduced to a range from 20 μm to 70 μm.

It is noted that, since only one exposure process and one development process are required to form the transparent electrode unit 211 and the peripheral wiring unit 31 according to the method of this invention, the fabricating process of this invention is thus simplified and has greater efficiency over the conventional method.

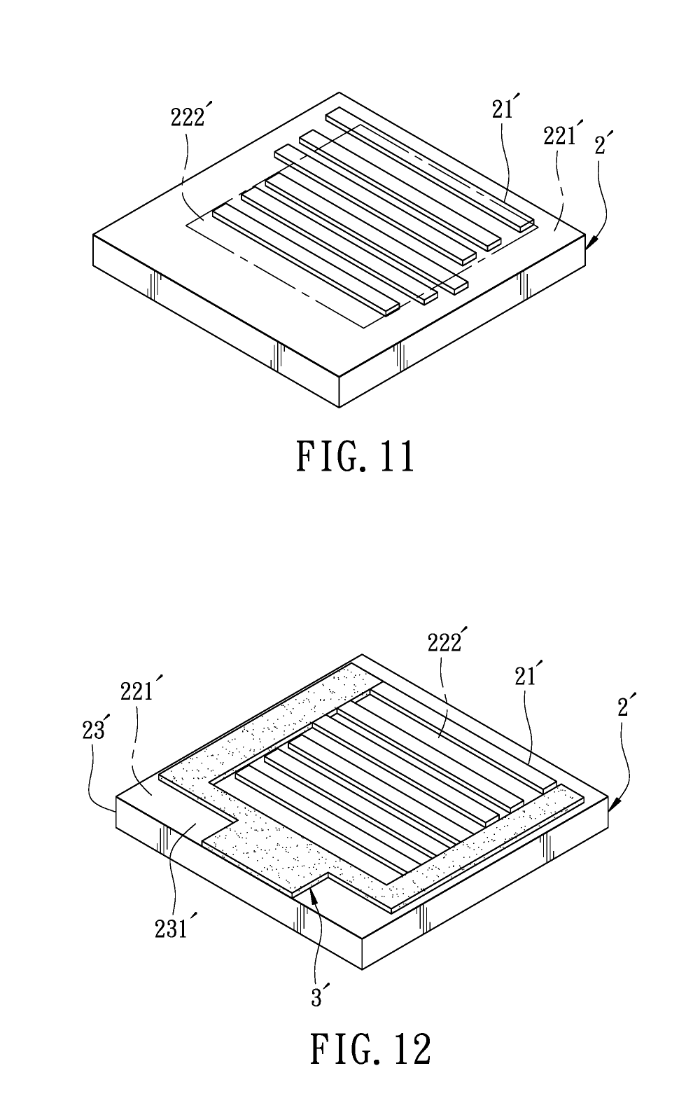

FIGS. 11 to 15 illustrate consecutive steps of a method for fabricating a peripheral wiring unit of the second preferred embodiment according to this invention.

Referring to FIGS. 11 and 12, a photosensitive conductive layer 3′ is formed on a peripheral region 221′ of a substrate 2′ which includes a patterned transparent electrode unit 21′. The substrate 2′ further has a window region 222′ surrounded by the peripheral region 221′. The transparent electrode unit 21′ is formed by patterning a transparent conductive layer made of a transparent conductive material before the photosensitive conductive layer 3′ is formed on the peripheral region 221′. The patterned transparent electrode unit 21′ is primarily formed on the window region 222′, and has an end portion extending into the peripheral region 221′. Specifically, the patterned transparent electrode unit 21′ has a plurality of strip structures each of which has an end side electrically connected with the photosensitive conductive layer 3′. The photosensitive conductive layer 3′ is identical to that in the first preferred embodiment, and thus a detailed description thereof is omitted herein for the sake of brevity. In this embodiment, the substrate 2′ further includes a transparent plate 23′ having an inner surface 231′. The transparent electrode unit 21′ and the photosensitive conductive layer 3′ are formed on the inner surface 231′ of the transparent plate 23′.

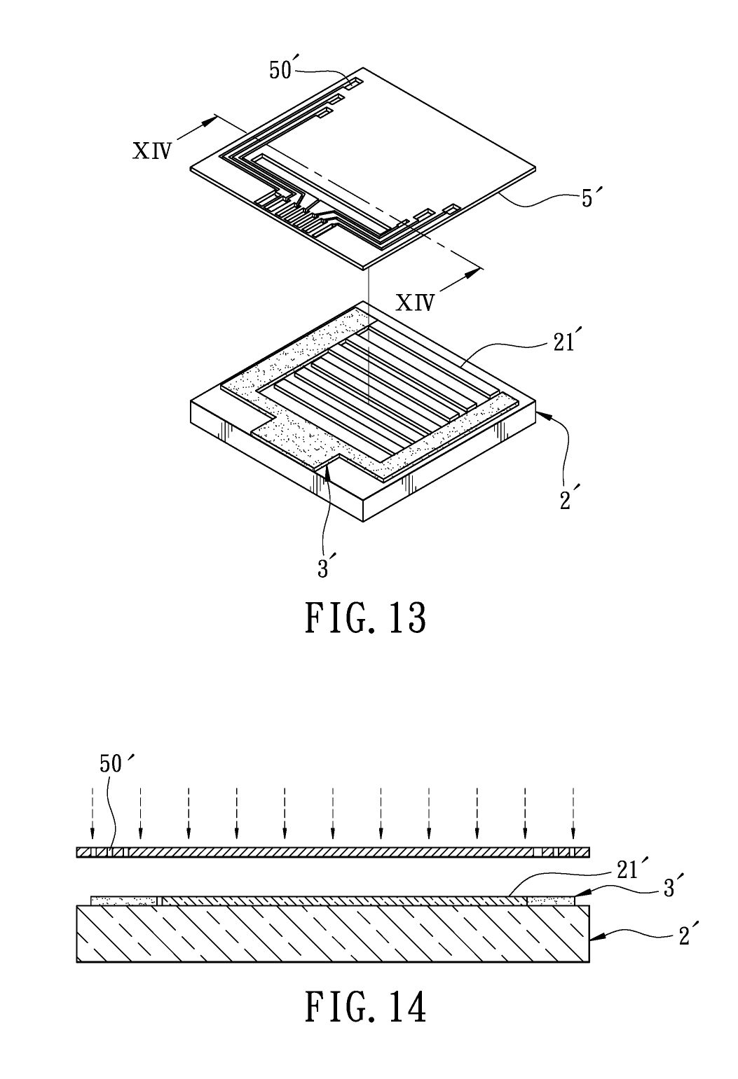

Referring to FIGS. 13 and 14, light passes through a photomask 5′ to the photosensitive conductive layer 3′ so as to expose the photosensitive conductive layer 3′. Since the patterned transparent electrode unit 21′ in this embodiment is already formed before the photosensitive conductive layer 3′ is formed, the design for light transmissible regions 50′ of the photomask 5′ is different from that in the first preferred embodiment. That is, the light transmissible regions 50′ are merely formed in the photomask 5′ corresponding in position to a wiring unit-forming portion of the peripheral region 221′ of the substrate 2′ shown in FIG. 12. Ultraviolet light passing through the light transmissible regions 50′ directly exposes the photosensitive conductive layer 3′ so that exposed portions of the photosensitive conductive layer 3′ are cured.

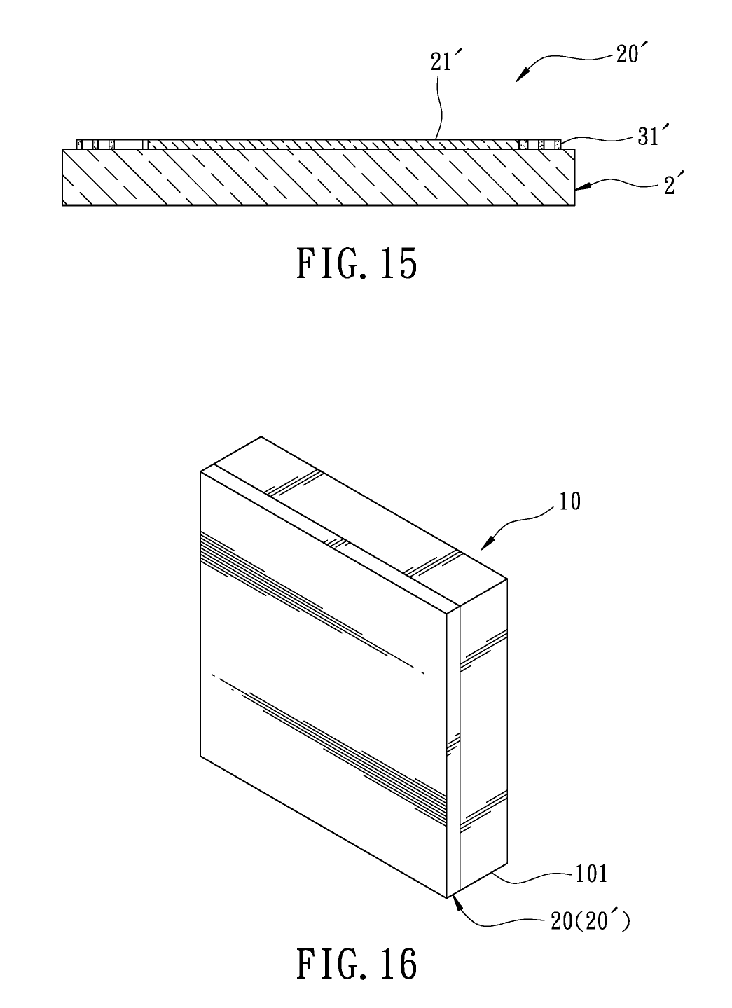

Referring to FIG. 15, the photosensitive conductive layer 3 thus exposed is further developed. Accordingly, a peripheral wiring unit 31′ is formed on the peripheral region 221′ of the substrate 2′. The developer used in this embodiment is identical to that used in the first preferred embodiment.

Then, the peripheral wiring unit 31′ is further cured by a hot baking process so as to improve degree of curing for the peripheral wiring unit 31′ and obtain a touch panel 20′ with a stable structure. Likewise, the touch panel 20′ can be packaged together with other electronic components to form a display apparatus.

Preferably, referring back to FIGS. 12, 14 and 15, since the transparent electrode unit 21′ contacts and partially underlies the photosensitive conductive layer 3′, the peripheral wiring unit 31′ is thus electrically connected to the transparent electrode unit 21′.

The fabrication method of the second preferred embodiment is also capable of reducing the line widths and line spacing of the peripheral wiring unit 31′ to a range from 20 μm to 70 μm by applying a photosensitive conductive material and the exposure and development techniques. It is further noted that the position precision and wire integrity are maintained while the line widths and line spacing of the peripheral wiring unit 31′ are reduced. Accordingly, failure of the touch panel 20 can be alleviated.

Referring to FIGS. 9 and 10, the touch panel 20 made according to the first preferred embodiment of this invention includes the substrate 2 and the peripheral wiring unit 31 formed on the substrate 2.

The substrate 2 has the window region 222 and the peripheral region 221 surrounding the window region 222, and includes the patterned transparent electrode unit 211 and the patterned peripheral transparent lead unit 212. The patterned transparent electrode unit 211 is made of the transparent conductive material and is formed on the window region 222. The patterned peripheral transparent lead unit 212 extends from the transparent electrode unit 211 to the peripheral region 221. The peripheral transparent lead unit 212 is also made of a transparent conductive material.

The peripheral wiring unit 31 is made of the photosensitive conductive material by exposure and development, and is formed on the peripheral region 221 of the substrate 2. The peripheral wiring unit 31 includes a plurality of peripheral wires 311 having widths ranging from 20 μm to 70 μm. The spacing between two adjacent ones of the peripheral wires 311 ranges from 20 μm to 70 μm.

The photosensitive conductive material is composed of the photosensitive material and a plurality of electrically conductive particles each having a particle size ranging from 1 μm to 10 μm. The electrically conductive particles are gold particles, silver particles, copper particles, aluminum particles, nickel particles, or combinations thereof. Moreover, the weight ratio of the electrically conductive particles to the photosensitive material ranges from 80:20 to 90:10.

Preferably, the peripheral transparent lead unit 212 of the substrate 2 underlies the peripheral wiring unit 31. Accordingly, the peripheral wiring unit 31 is electrically connected to the transparent electrode unit 211 on the window region 222.

Referring to FIGS. 10 and 15, the touch panel 20′ of the second preferred embodiment of this invention includes the substrate 2′ and the peripheral wiring unit 31′ disposed on the substrate 2′. The substrate 2′ also has the transparent electrode unit 211′ formed on the window region 222′. The peripheral wiring unit 31′ is made of the photosensitive conductive material using photolithography. The touch panel 20′ made according to the second preferred embodiment differs from that of the first preferred embodiment in that the substrate 2′ does not include the peripheral transparent lead unit 212. During formation of the transparent electrode unit 211′, a plurality of end sides of the strip structures of the transparent electrode unit 211′ underlie an end of the peripheral wiring unit 31′. Accordingly, the connection makes the transparent electrode unit 211′ electrically connected to the peripheral wiring unit 31′.

In the touch panels 20, 20′ of the first and second preferred embodiments, since the peripheral wiring unit 31, 31′ are made by exposing and developing a photosensitive conductive material, the peripheral wiring units 31, 31′ can maintain the precision in wiring size and position while reducing line width and line spacing. The wire integrity can also be maintained. Accordingly, the area of the peripheral region can be reduced without adversely affecting the normal operation of the touch panels 20, 20′, thereby raising the area percentage of the window region on the substrate 2, 2′.

Referring to FIG. 16, a touch screen display apparatus 10 of the preferred embodiment according to this invention comprises the touch panel 20 which is made according to the first preferred embodiment, and a display panel 101 disposed on the touch panel 20. The display panel 101 is disposed on the transparent electrode unit 211 (as shown in FIG. 9) of the touch panel 20. Alternatively, the touch screen display apparatus 10 can be formed by using the touch panel 20′ of the second preferred embodiment in combination with the display panel 101. Likewise, a relatively large touch area and display area can be provided.

The touch screen display apparatus 10 may be a mobile phone, a digital camera, a personal digital assistant (PDA), a laptop, a desktop computer, a television, an automotive display or a portable DVD player.

By utilizing the aforesaid peripheral wiring unit 31, 31′ made according to the method of this invention, the area proportion of the window region 222, 222′ of the touch panel 20, 20′ may be raised while simultaneously maintaining good functionality and normal operation of the touch panel 20, 20′. Accordingly, compared to a conventional touch screen display apparatus with the same size scale, the touch screen display apparatus 10 of this invention provides a relatively large touch area and display area.

While the present invention has been described in connection with what are considered the most practical and preferred embodiments, it is understood that this invention is not limited to the disclosed embodiments but is intended to cover various arrangements included within the spirit and scope of the broadest interpretations and equivalent arrangements.

What is claimed is:

1. A method for fabricating a peripheral wiring unit of a touch panel, comprising the following steps:
(a) forming a transparent conductive layer on a substrate, the substrate including a peripheral region and a window region surrounded by the peripheral region, and forming a photosensitive conductive layer on the peripheral region of the substrate, such that the photosensitive conductive layer at least partially overlies the transparent conductive layer;
(b) exposing the photosensitive conductive layer by using a photomask; and
(c) developing the exposed photosensitive conductive layer to form a peripheral wiring unit on the peripheral region of the substrate.

2. The method of claim 1, wherein step (a) comprises: forming the transparent conductive layer on the peripheral region and the window region; and
forming the photosensitive conductive layer, such that the photosensitive conductive layer totally overlies the transparent conductive layer.

3. The method of claim 2, wherein step (a) comprises, after forming the photosensitive conductive layer, forming a photoresist layer to cover the transparent conductive layer and the photosensitive conductive layer;
step (b) comprises simultaneously exposing the photosensitive conductive layer and the photoresist layer by using the photomask; and
step (c) comprises, before developing the exposed photosensitive conductive layer, developing the photoresist layer to form a patterned photoresist layer on the window region and the peripheral region.

4. The method of claim 3, further comprising, after step (c), (d) etching the transparent conductive layer that is exposed from the patterned photoresist layer, and removing the patterned photoresist layer to form a transparent electrode unit on the window region and a peripheral transparent lead unit underneath the peripheral wiring unit.

5. The method of claim 4, wherein the photosensitive conductive layer in step (a) is thermosetting, the method further comprising, after step (d), hot baking the peripheral wiring unit.

6. The method of claim 1, wherein step (a) comprises: forming the transparent conductive layer on the window region and the peripheral region, and wherein in step (a), before forming the photosensitive conductive layer, the transparent conductive layer is patterned to form a transparent electrode unit.

7. The method of claim 6, wherein step (c) comprises: forming the peripheral wiring unit to electrically connect to the transparent electrode unit.

8. The method of claim 1, wherein the photosensitive conductive layer in step (a) is made of a photosensitive conductive material with viscosity ranging from 15000 mPa·S to 25000 mPa·S.

9. The method of claim 1, wherein the photosensitive conductive layer is made of a photosensitive conductive material with electrical resistivity ranging from 1.5*10⁻⁶ Ω·cm to 2.5*10⁻⁶ Ω·cm.

10. The method of claim 1, wherein the photosensitive conductive layer is made of a photosensitive conductive material containing a photosensitive material and a plurality of electrically conductive particles, the weight ratio of the electrically conductive particles to the photosensitive material in the photosensitive conductive material ranging from 90:10 to 80:20.

11. The method of claim 1, wherein the photosensitive conductive layer in step (a) is thermosetting, the method further comprising hot baking the peripheral wiring unit after step (c).

12. The method of claim 1, wherein the photosensitive conductive layer in step (a) has a thickness ranging from 3 μm to 10 μm.

13. The method of claim 1, wherein step (b) is conducted at an exposure dose ranging from 50 mJ/cm² to 200 mJ/cm².
